(19) United States
(12) Patent Application Publication
(10) Pub. No.: US 2003/0185969 A1
(43) Pub. Date: Oct. 2, 2003

(54) Method of manufacturing organic electroluminescent device

(75) Inventors: Yoshitaka Nishio, Hirakata-City (JP); Hiroshi Matsuki, Hashima-gun (JP)

Correspondence Address: McDERMOTT, WILL & EMERY, 600 13th Street, N.W., Washington, DC, 20005-3096, US

(73) Assignee: Sanyo Electric Co., Ltd.

(21) Appl. No.: 10/378,930

(22) Filed: Mar. 5, 2003

(30) Foreign Application Priority Data
Mar. 5, 2002 (JP) JP2002-059588

(51) Int. Cl. B05D 5/12

(52) U.S. Cl. 427/66

(57) ABSTRACT

An organic EL device is fabricated by a novel method to reduce the occurrence of poor luminescence in the organic EL device. An anode layer, an organic luminescent element layer including a hole transporting layer, a luminescent layer, and an electron transporting layer, and a cathode layer are laminated in this order on a substrate to fabricate an organic EL device. Here, one or more dummy substrates are initially introduced into the system for evaporating the organic luminescent element layer on the substrate. The organic layers are evaporated on the dummy substrate so that foreign particles adhere thereto. Then, the substrate to be a product is introduced, and the organic luminescent element layer is evaporated thereon.

### BACKGROUND OF THE INVENTION

1. Field of the Invention

The present invention relates to a method of manufacturing an organic electroluminescent device, and more particularly to a technology for solving a problem of a defect of luminescence in an organic electroluminescent device.

2. Description of the Related Art

Organic electroluminescent displays (hereinafter, also referred to as “organic EL displays” or “organic EL panels”) are attracting attention as new flat-type displays. In particular, active matrix type organic EL displays having thin film transistors (hereinafter, also referred to as “TFTs”) as switching elements are regarded as sweeping out the currently prevailing liquid crystal displays in the near future, and are in a fierce development race for practical application.

FIG. 1 schematically shows the sectional structure of a typical organic electroluminescent device (hereinafter, also referred to as “organic EL device”). The organic EL device 100 has the structure in which an anode layer 20, an organic luminescent element layer 80, and a cathode layer 60 are laminated on a substrate 10 in order. The organic luminescent element layer 80 includes organic layers which function as a luminescent element such as a hole transporting layer 30, a luminescent layer 40, and an electron transporting layer 50, which are laminated on the anode layer 20 in this order. When a voltage is applied across the anode layer 20 and the cathode layer 60, holes injected from the anode layer 20 are transported to the luminescent layer 40 by the hole transporting layer 30. Electrons injected from the cathode layer 60 are transported to the luminescent layer 40 by the electron transporting layer 50. The electrons and the holes are recombined with each other at the interface or inside of the luminescent layer 40. The resulting energy excites electrons in the organic molecules of the luminescent layer 40. Then, the excited electrons relax with fluorescence emission. At least either one of the anode layer 20 and the cathode layer 60 is made of a transparent or semi-transparent material that transmits light of visible light range. The light emitted from the luminescent layer 40 is taken out through the electrode layer.

As above, unlike liquid crystal displays, organic EL displays have self-emission devices. This eliminates the need for a backlight which is indispensable to liquid crystal displays, promising apparatuses of yet thinner and lighter weight. When poor luminescence occurs for any reason, however, dead pixels appear on-screen with deterioration in screen visibility, sometimes presenting an obstacle to the display function. It has therefore been a significant challenge to ascertain the cause of the poor luminescence and prevent it effectively so that organic EL displays having fewer dead pixels or no dead pixel can be fabricated with high yield.

### SUMMARY OF THE INVENTION

The present invention has been made in view of the foregoing circumstances and an object thereof is to provide a technology for reducing the occurrences of poor luminescence in an organic EL device.

A preferred embodiment according to the present invention relates to a method of manufacturing an organic electroluminescent device. This method comprises: introducing one or more dummy substrates into a system for depositing an organic layer on a substrate, and making foreign particles lying in the system adhere to the dummy substrate; and introducing, after said introducing one or more dummy substrates, a plurality of substrates into the system in succession to deposit the organic layer on the surface of each of the substrates. The dummy substrate may be the same as or different from the substrates to be products. It is essential only that before the evaporation of the organic layers on the substrates to be products, foreign particles in the system are made to adhere and removed out of the system. The number of foreign particles remaining in the system is thus reduced to minimize the adhesion of foreign particles to the product substrates.

The relationship between the number of dummy substrates introduced into the system in said introducing one or more dummy substrates and the number of foreign particles adhering to a substrate in said introducing a plurality of substrates may be acquired to determine the number of dummy substrates to be introduced based on the relationship. The number of dummy substrates to be introduced may be determined system by system or each time the step of depositing the organic layer is performed. Consequently, it is possible to avoid the situations that too small a number of dummy substrates allows foreign particles to adhere to the product substrates with a deterioration in yield, and conversely that the introduction of too many dummy substrates wastes unnecessary fabrication cost.

In said introducing one or more dummy substrates, a hole transporting layer may be deposited on the surface of a substrate having an anode layer provided thereon. When an anode layer, a hole transporting layer, a luminescent layer, an electron transporting layer, and a cathode layer are laminated on a substrate in order, it is the hole transporting layer that is the first to be evaporated among the organic layers. Introducing the dummy substrate in advance of the evaporation of the hole transporting layer can reduce the adhesion of foreign particles to the product substrates, thereby avoiding poor evaporation of the organic layers.

It is to be noted that any arbitrary combination of the above-described structural components, and expressions changed between a method, an apparatus, a system and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

FIG. 1 is a diagram schematically showing the sectional structure of a typical organic EL device.

FIG. 2 is a diagram schematically showing the sectional structure of an organic EL device for situations where a foreign particle adheres to the surface in the process of fabrication.

FIG. 3 is a flowchart showing a method of manufacturing an organic EL device according to an embodiment.

FIGS. 4A and 4B are diagrams showing the distributions of dead pixels in organic EL panels.

FIG. 5 is a chart showing measurements of the numbers of dead pixels in organic EL panels that were individually fabricated by depositing organic layers after a plurality of substrates were introduced into the evaporation system in succession.

FIG. 6 is a graphic representation of the measurements shown in FIG. 5, showing the relationship between the round of deposition of the hole transporting layer and the number of dead pixels.

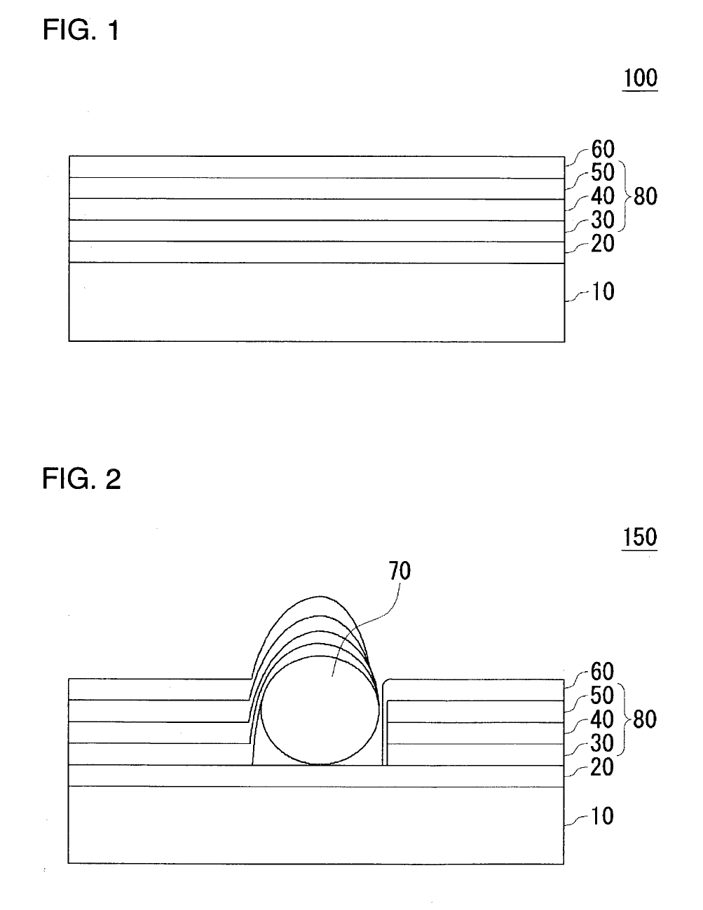

### DETAILED DESCRIPTION OF THE INVENTION

FIG. 2 schematically shows the sectional structure of an organic EL device for situations where a foreign particle adheres to the surface in the process of fabrication. Incidentally, the diagram is intended only to give plain schematic representation of the adherence of a foreign particle, not to show the relationship between the actual thicknesses of the substrate, individual electrode layers, and organic layers, and the size of the foreign particle.

A substrate 10 is made of an insulative substance such as glass. In the case of an active matrix type organic EL panel, for example, the substrate 10 has the structure in which driving circuits containing switching elements such as TFTs are formed on an insulative substrate, and a planarization film and the like are formed thereon. As employed in this specification, the substrate 10 shall also include such configuration as the driving circuits.

An anode layer 20 is formed on the substrate 10. The anode layer 20 is made of such material as indium tin oxide (ITO), tin oxide (SnO₂), or indium oxide (In₂O₃). ITO is typically used because of its hole injection efficiency and low surface resistance. Since ITO has high transparency to visible light, light emitted from a luminescent layer 40 is taken out through the ITO anode layer 20. An additional planarization film may be deposited on the anode layer 20 if necessary.

An organic luminescent element layer 80 including the hole transporting layer 30, the luminescent layer 40, and an electron transporting layer 50 is formed on the anode layer 20. The hole transporting layer 30 is made of such material as N,N′-di(naphthalene-1-yl)-N,N′-diphenyl-benzidine (hereinafter, referred to as “material 1”), 4,4′,4″-tris(3-methylphenylphenylamino)triphenylamine (MTDATA), or N,N′-diphenyl-N,N′-di(3-methylphenyl)-1,1′-biphenyl-4,4′-diamine. The luminescent layer 40 is made of such material as aluminum-quinoline complex (Alq₃) or bis (10-hydroxybenzo[h]quinolinato) beryllium (Bebq₂) containing a quinarcridon derivative. The electron transporting layer 50 is made of such material as Alq₃ or Bebq₂.

A cathode layer 60 is formed on the electron transporting layer 50. The cathode layer 60 is made of such material as an aluminum alloy containing a trace quantity of lithium, a magnesium indium alloy, or a magnesium silver alloy. The cathode layer 60 may have a double-layer structure having a lithium fluoride (LiF) layer and an aluminum (Al) layer in this order from the electron transporting layer 50.

In general, the organic layers including the hole transporting layer 30, the luminescent layer 40, and the electron transporting layer 50 are formed by vacuum evaporation in a multi-chamber type fabrication system having a plurality of formation chambers. In some cases, such matter as inorganic or organic substances having peeled off the organic EL devices fabricated last time and organic substances not evaporated onto substrates may remain and adhere to the surface of the substrate introduced newly. When the organic luminescent element layer 80 is evaporated with the foreign particle 70 adhering on the anode layer 20, the organic substance is less evaporated on the area beneath the foreign particle 70 and on the periphery thereof. The organic luminescent element layer 80 may thus fail to cover the foreign particle 70, possibly leaving a gap around the foreign particle 70. A cathode layer 60 is then laminated on the organic luminescent element layer 80. Here, if the cathode material gets into the gap, the anode layer 20 and the cathode layer 60 can make contact at that portion with the result of a short.

With the anode layer 20 and the cathode layer 60 shorted, an intensive current flows through the shorted portion when a voltage is applied between the anode layer 20 and the cathode layer 60. This precludes a current flow in the luminescent layer 40, making a non-luminescent pixel where no luminescence occurs across the entire pixel. Organic EL panels containing a number of organic EL devices 150 having such defects can no longer be shipped as products. This means a lower yield.

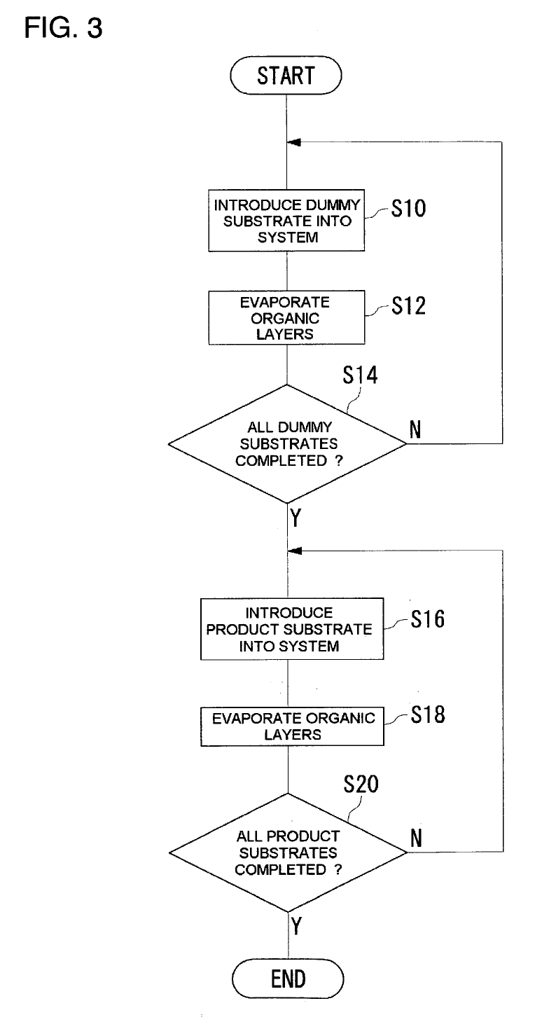

FIG. 3 is a flowchart showing a method of fabricating an organic EL device according to an embodiment of the present invention. In the present embodiment, before substrates are introduced to the system for depositing the organic layers, one or more dummy substrates are introduced into the system to make foreign particles lying in the system adhere to the dummy substrate. This decreases the number of foreign particles remaining in the system, minimizing the number of foreign particles to adhere to the surfaces of the substrates to be products.

Initially, a dummy substrate is introduced into the system for depositing the organic layers (S10). The organic layers are deposited on the dummy substrate (S12). These steps are repeated until the number of foreign particles remaining in the system seems to decrease sufficiently (N at S14). When the steps of removing foreign particles by using a dummy substrate are completed (Y at S14), then the substrates to be products are successively introduced into the system (S16) and subjected to organic layer evaporation (S18). These steps are repeated as many times as the number of product substrates (N at S20).

The dummy substrates may be simple insulative substrates having none of such circuits as a TFT. Consequently, it is possible to reduce the cost of the dummy substrates which make no product. The dummy substrates may be the same as the product substrates, or may be made identical to the product substrates at least in the surface layers. This can make the adsorption conditions on the surfaces of the dummy substrates the same as with the product substrates. It is therefore possible to avoid the situation that foreign particles less adsorbable to the dummy substrates remain in the system and get adsorbed by the product substrates. The surfaces of the dummy substrates may have a material or shape likely to adsorb foreign particles. For example, porous surface configuration may be adopted. This can promote the adhesion of the foreign particles in the system, allowing removal to outside the system. After the dummy substrates are introduced into the system, the adhesion of foreign particles is desirably effected by performing the step of evaporating the organic layers under the same conditions as with the product substrates. Nevertheless, the adhesion of foreign particles may be effected by leaving the dummy substrates in the system for a given length of time without the evaporation step. This can reduce the cost of the organic evaporation on the dummy substrates which make no product.

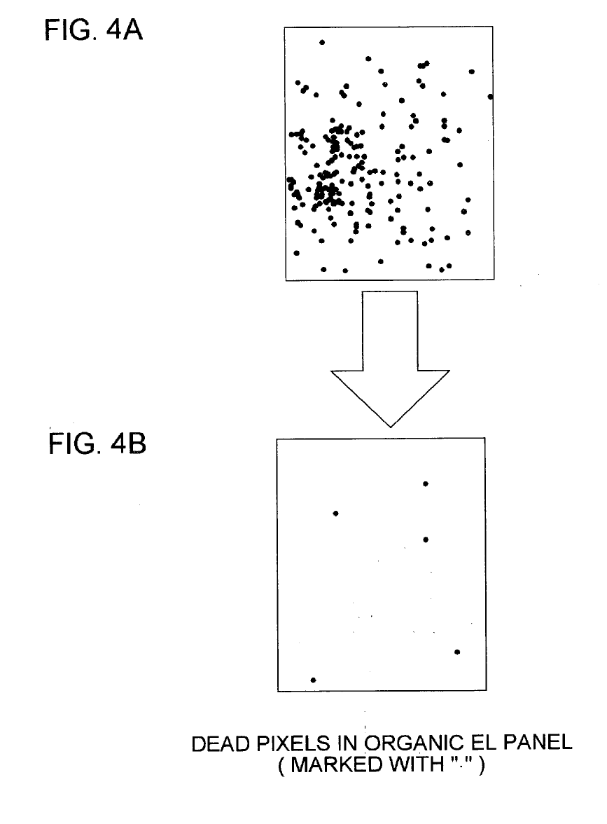

FIGS. 4A and 4B are diagrams showing the distributions of dead pixels in organic EL panels. The distributions of dead pixels were measured by checking the organic EL panels visually under a microscope or the like. FIG. 4A shows the distribution of dead pixels in an organic EL panel that was fabricated by depositing organic layers without dummy substrates being introduced into the evaporation system. This organic EL panel has too many dead pixels to function in order as a display. FIG. 4B shows the distribution of dead pixels in an organic EL panel that was fabricated by depositing organic layers after dummy substrates were introduced into the evaporation system for foreign particle removal. The number of dead pixels in this organic EL panel is significantly smaller than the number of dead pixels in the organic EL panel shown in FIG. 4A. It is apparent that introducing dummy substrates into the evaporation system in advance can reduce the occurrence of dead pixels greatly.

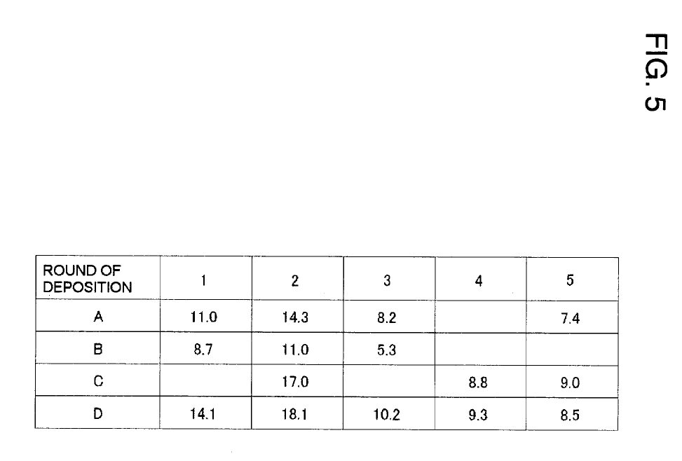

FIG. 5 shows measurements of the numbers of dead pixels in organic EL panels that were individually fabricated by depositing organic layers after a plurality of substrates were introduced into the evaporation system in succession. Five organic EL panels each having the hole transporting layers made of the diamine derivative specified with material 1 were fabricated and measured for the respective numbers of dead pixels. The experiment was performed four times, or for A, B, C, and D.

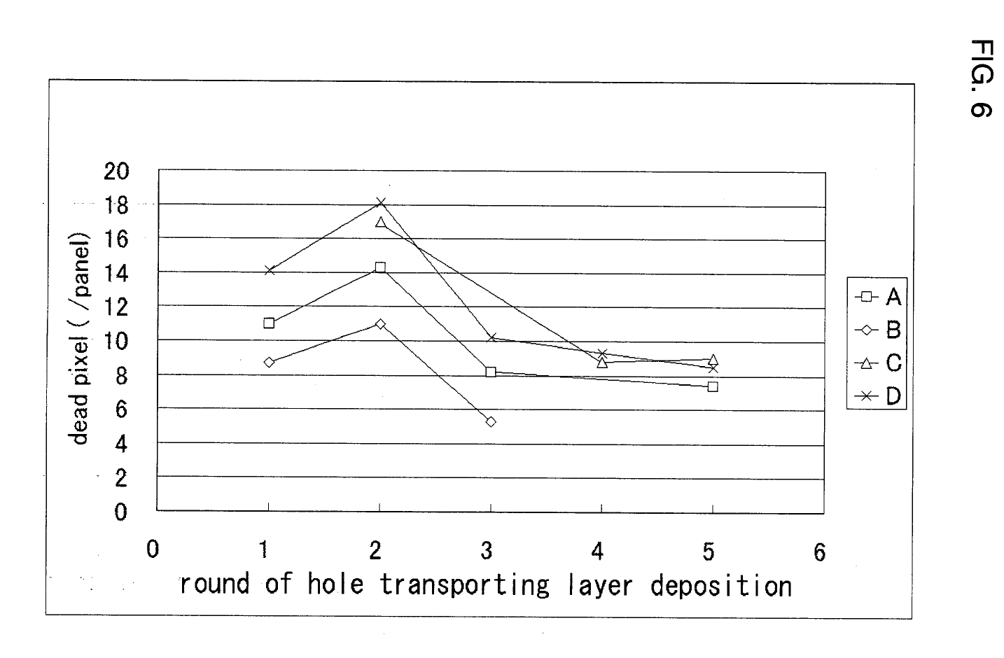

FIG. 6 is a graphic representation of the measurements shown in FIG. 5, showing the relationship between the round of the hole transporting layer deposition and the number of dead pixels in a panel. It can be seen from any of the experiments that the organic EL panel fabricated from the second substrate deposited is greater in the number of dead pixels than the organic EL panel fabricated from the first substrate deposited, whereas the third decreases in the number of dead pixels with an improvement in yield. The third and the subsequent, i.e., the fourth and the fifth, show nearly the same numbers of deal pixels. It is considered that introducing at least two dummy substrates can provide the effect of reducing the occurrence of dead pixels ascribable to interelectrode shorts. The reason why the number of dead pixels does not reach zero seems that dead pixels can also occur from factors other than interelectrode shorts. It can be seen from the foregoing results that the introduction of two or more dummy substrates is desirable.

The appropriate number of dummy substrates to be introduced may be determined by introducing a plurality of substrates for organic layer evaporation in succession and measuring the relationship between the round of deposition of the organic layer films and the number of dead pixels in the organic EL panel deposited, as in the foregoing experiments. Alternatively, the number of dummy substrates necessary for the number of foreign particles remaining in the system to decrease sufficiently may be acquired by measuring the relationship between the round of deposition of the organic layer films and the number of foreign particles remaining in the system. This makes it possible to determine the appropriate number of dummy substrates to be introduced system by system. The measurement mentioned above may be performed each time the step of evaporation the organic layers is performed. Moreover, a sensor for measuring the number of foreign particles may be provided in the formation chamber of the system. Here, dummy substrates are introduced until the number of foreign particles decreases sufficiently.

A system may be provided containing a table in which appropriate numbers of dummy substrates are stored in association with the conditions for the step of evaporating the organic layers. For example, appropriate numbers of dummy substrates to be introduced may be previously determined and stored in the form of a table in association with such conditions as the material and size of the substrate, the thicknesses and materials of layers already evaporated on the substrate, the type of the evaporation system, the types of organic substances to be evaporated, the sizes of the formation chambers, and the temperatures and degrees of vacuum in the formation chambers. Here, the number of dummy substrates to be introduced shall be output when users enter the conditions.

As mentioned above, the defect of the organic EL device such as poor luminescence across the entire pixel caused by the short, and poor luminescence around the foreign particle caused by poor evaporation of the organic luminescent element layer 80 can be effectively reduced according to the embodiments.

The present invention has been described based on embodiments which are only exemplary. It will be understood by those skilled in the art that there exist other various modifications to the combination of each component and process described above and that such modifications are encompassed by the scope of the present invention. Such modifications will be described hereinbelow.

In the foregoing embodiment, the organic luminescent element layer 80 includes the hole transporting layer 30, the luminescent layer 40, and the electron transporting layer 50. Nevertheless, the hole transporting layer 30 and the electron transporting layer 50 may be provided depending on the characteristics of the organic EL device. A plurality of hole transporting layers 30 or electron transporting layers 50 may also be provided.

Although the present invention has been described by way of exemplary embodiments, it should be understood that many changes and substitutions may further be made by those skilled in the art without departing from the scope of the present invention which is defined by the appended claims.

What is claimed is:

1. A method of manufacturing an organic electroluminescent device, comprising:
introducing one or more dummy substrates into a system for depositing an organic layer on a substrate, and making foreign particles lying in the system adhere to the dummy substrate; and
introducing, after said introducing one or more dummy substrates, a plurality of substrates into the system in succession to deposit the organic layer on a surface of each of the substrates.

2. A method of manufacturing an organic electroluminescent device according to claim 1, wherein a relationship between the number of dummy substrates introduced into the system in said introducing one or more dummy substrates and the number of foreign particles adhering to the substrate in said introducing a plurality of substrates is acquired to determine the number of dummy substrates to be introduced based on the relationship.

3. A method of manufacturing an organic electroluminescent device according to claim 1, wherein in said introducing one or more dummy substrates, a hole transporting layer is deposited on a surface of a substrate having an anode layer provided thereon.

4. A method of manufacturing an organic electroluminescent device according to claim 2, wherein in said introducing one or more dummy substrates, a hole transporting layer is deposited on a surface of a substrate having an anode layer provided thereon.
